(19) United States
(12) Patent Application Publication
(10) Pub. No.: US 2011/0093222 A1
(43) Pub. Date: Apr. 21, 2011

(54) POWER CYCLING TEST APPARATUS

(75) Inventor: JIN-LIANG XIONG, Shenzhen City (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/650,427

(22) Filed: Dec. 30, 2009

(30) Foreign Application Priority Data
Oct. 19, 2009 (CN) 200910308456.3

(51) Int. Cl. G06F 19/00; G01R 21/00

(52) U.S. Cl. 702/60

(57) ABSTRACT

A power cycling test apparatus includes a sampling circuit, a controlling circuit, and a powering circuit. A first terminal of the sampling circuit is connected to an interface of a computer. A first terminal of the controlling circuit is connected to a second terminal of the sampling circuit. A second terminal of the controlling circuit is connected to a third terminal of the sampling circuit. A first terminal of the powering circuit is connected to a third terminal of the controlling circuit. A second terminal of the powering circuit is connected to an alternating current power supply. A third terminal of the powering circuit is connected to a power supply unit of the computer. The power cycling test apparatus directs the alternating current power supply to supply power to the power supply unit.

### BACKGROUND

1. Technical Field

The present disclosure relates to a power cycling test apparatus.

2. Description of Related Art

A computer reliability test includes a power cycling test, in which a power-up period, a power-off period, and a cycling time of an alternating current (AC) power supply are set. The AC power supply supplies power to computers being tested to determine if the computers are reliable by registering a number of successful power-ups. However, the AC power supply will continue to supply power to the computers even when the computers have failed to power up. Computer function cannot be tracked when power-up fails. Further, the power-up period is often set too long to ensure that the computers have time to power on.

### BRIEF DESCRIPTION OF THE DRAWINGS

FIG. 1 is a block diagram of an exemplary embodiment of a power cycling test apparatus.

FIG. 2 is a circuit diagram of an exemplary embodiment of the power cycling test apparatus of FIG. 1.

### DETAILED DESCRIPTION

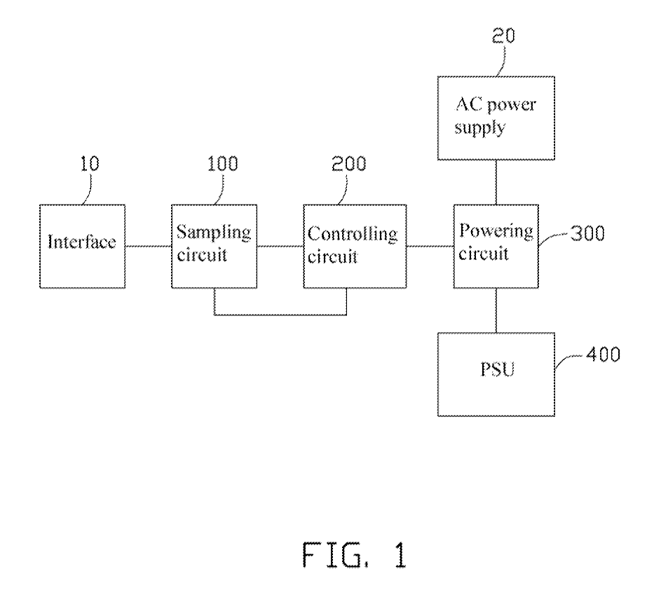

Referring to FIG. 1, an exemplary embodiment of a power cycling test apparatus includes a sampling circuit 100, a controlling circuit 200, and a powering circuit 300.

A first terminal of the sampling circuit 100 is connected to an interface 10 of a computer. A second terminal of the sampling circuit 100 is connected to a first terminal of the controlling circuit 200. The sampling circuit 100 receives a first signal of the interface 10 and converts the first signal to a second signal.

A second terminal of the controlling circuit 200 is connected to a third terminal of the sampling circuit 100. A third terminal of the controlling circuit 200 is connected to a first terminal of the powering circuit 300. The controlling circuit 200 receives the first signal and second signal and outputs a third signal.

A second terminal of the powering circuit 300 is connected to an alternating current (AC) power supply 20. A third terminal of the powering circuit 300 is connected to a power supply unit (PSU) 400 of the computer. The powering circuit 300 receives the third signal, directing connection of the AC power supply 20 and the PSU 400.

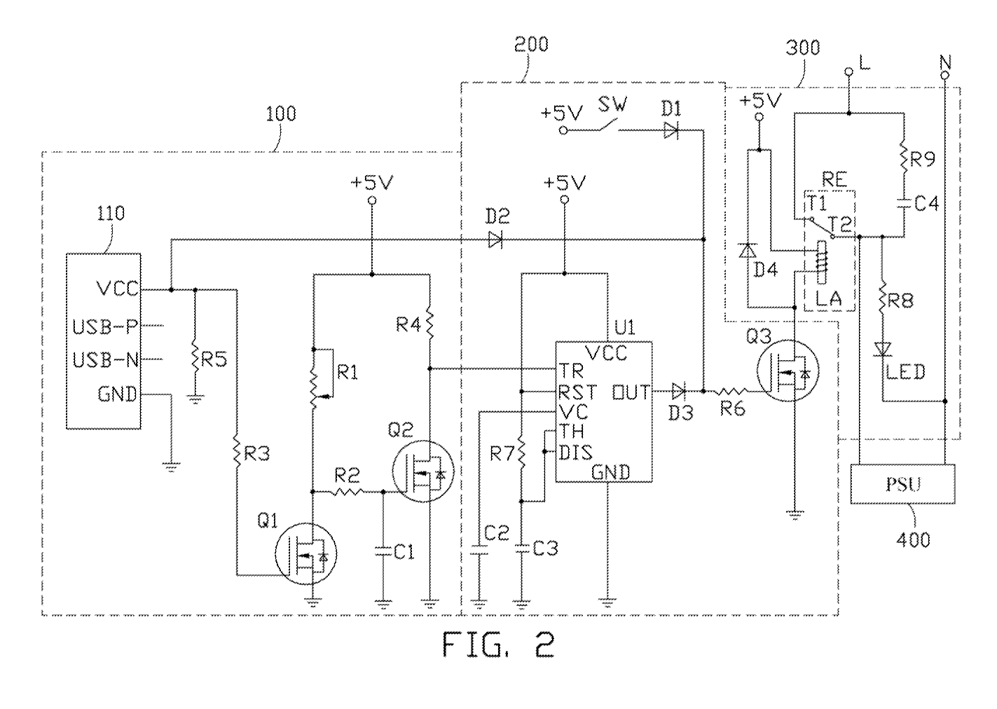

Referring to FIG. 2, the sampling circuit 100 includes a universal serial bus (USB) interface 110, a variohm R1, a capacitor C1, a first metal oxide semiconductor field effect transistor (MOSFET) Q1, a second MOSFET Q2, and resistors R2-R5.

The USB interface 110 functions as the first terminal of the sampling circuit 100, to connect to the interface 10 of the computer. The USB interface 110 includes a power terminal VCC, a ground terminal GND, and two signal terminals USB-P and USB-N. The two signal terminals USB-P and USB-N are suspended. The ground terminal GND is grounded. A gate of the first MOSFET Q1 is connected to the power terminal VCC of the USB interface 110 via the resistor R3. A drain of the first MOSFET Q1 is connected to a +5 volt (V) power supply via the variohm R1. A source of the first MOSFET Q1 is grounded. A gate of the second MOSFET Q2 is connected to the drain of the first MOSFET Q1 via the resistor R2 and grounded via the capacitor C1. A drain of the second MOSFET Q2 is connected to the +5V power supply via the resistor R4. A source of the second MOSFET Q2 is grounded. The drain of the second MOSFET Q2 functions as the second terminal of the sampling circuit 100. The power terminal VCC of the USB interface 110 functions as the third terminal of the sampling circuit 100 and is grounded via the resistor R5.

The controlling circuit 200 includes a trigger U1, a third MOSFET Q3, a switch SW, diodes D1-D3, resistors R6-R7, and capacitors C2 and C3.

The trigger U1 is an NE555 trigger including a power terminal VCC, a ground terminal GND, a threshold terminal TH, a trigger terminal TR, a control terminal VC, a reset terminal RST, a discharge terminal DIS, and an output terminal OUT.

The power terminal VCC of the trigger U1 is connected to the +5V power supply. The ground terminal GND of the trigger U1 is grounded. The control terminal VC is grounded via the capacitor C2. The threshold terminal TH is connected to the discharge terminal DIS and is grounded via the capacitor C3. The threshold terminal TH is also connected to the +5V power supply via the resistor R7. The reset terminal RST is connected to the +5V power supply. The trigger terminal TR functions as the first terminal of the controlling circuit 200, to connect to the drain of the second MOSFET Q2. The output terminal OUT of the trigger U1 is connected to an anode of the diode D3.

A first terminal of the switch SW is connected to the +5V power supply. A second terminal of the switch SW is connected to an anode of the diode D1.

An anode of the diode D2 functions as the second terminal of the controlling circuit 200, to connect to the power terminal VCC of the USB interface 110. A cathode of the diode D2 is connected to cathodes of the diode D1 and the diode D3.

A gate of the third MOSFET Q3 is connected to the cathode of the diode D3 via the resistor R6. A source of the third MOSFET Q3 is grounded. A drain of the third MOSFET Q3 functions as the third terminal of the controlling circuit 200, to connect to the first terminal of the powering circuit 300.

The powering circuit 300 includes a relay RE, a diode D4, a LED, a capacitor C4, and resistors R8 and R9.

The relay RE includes a coil LA, a first contact T1, and a second contact T2. A first terminal of the coil LA is connected to the +5V power supply. A second terminal of the coil LA functions as the first terminal of the powering circuit 300, to connect to the drain of the third MOSFET Q3. The second terminal of the coil LA is also connected to an anode of the diode D4. A cathode of the diode D4 is connected to the +5V power supply. The first contact T1 functions as the second terminal of the powering circuit 300, to connect to a hot line L of the AC power supply 20. The second contact T2 functions as the third terminal of the powering circuit 300, to connect to the PSU 400. The first contact T1 contacts the second contact T2 in the presence of current through the coil LA. The first contact T1 does not contact the second contact T2 when in the absence of current through the coil LA.

The second contact T2 is also connected to an anode of the LED via the resistor R8. A cathode of the LED is connected to a ground line N of the AC power supply 20. The ground line N of the AC power supply 20 is connected to the PSU 400.

The second contact T2 is also connected to the hot line L of the AC power supply 20 via the capacitor C4 and resistor R9 in series.

The trigger U1 operates when the reset terminal RST is at a high level, and does not operate when the reset terminal RST is at a low level. Therefore, in the exemplary embodiment, the trigger U1 always operates because the reset terminal RST is connected to the +5V power supply.

The AC power supply 20 supplies power to the computer as follows. The voltage of the power terminal VCC of the USB interface 110 is 0 volt (V) before the computer is powered on. The first MOSFET Q1 is turned off. The +5V power supply charges the capacitor C1 via the variohm R1 and resistor R2. The second MOSFET Q2 is turned on when the voltage of the capacitor C1 exceeds the threshold voltage of the second MOSFET Q2. The voltage of the drain of the second MOSFET Q2 is at a low level. The voltage of the trigger terminal TR of the trigger U1 is at a low level. The output terminal OUT of the trigger U1 is at a high level. The third MOSFET Q3 is turned on and current is generated through the coil LA. The coil LA produces a magnetic field which connects the first contact T1 with second contact T2. The hot line L is connected to the PSU 400 of the computer. Power is supplied to the computer and the LED is lit.

The period of the high level of the output terminal OUT of the trigger U1 is determined by a capacitance of the capacitor C3 and a resistance of the resistor R7. The period of the high level of the output terminal OUT of the trigger U1 is set to ensure that the computer can be powered on normally. The switch SW can turn on the third MOSFET Q3, omitting the charging time of the capacitor C1 to conserve testing time.

AC power supply 20 continually supplies power to the computer as follows. The voltage of the power terminal VCC of the USB interface 110 is +5V after the computer is powered on. The first MOSFET Q1 is turned on. The capacitor C1 discharges via the resistor R2 and the first MOSFET Q1. The second MOSFET Q2 is turned off when the voltage of the capacitor C1 falls below the threshold voltage of the second MOSFET Q2. The voltage of the drain of the second MOSFET Q2 is at a high level. The voltage of the trigger terminal TR of the trigger U1 is at a high level. The output terminal OUT of the trigger U1 is at a low level. The third MOSFET Q3 remains on for the anode of the diode D2 to connect to the power terminal VCC of the USB interface 110. The first contact T1 remains contacted with the second contact T2. The hot line L remains connected to the PSU 400 of the computer.

AC power supply 20 terminates power to the computer as follows. The computer initiates an operating system after being powered on. The operating system generates a shutdown instruction to shut down the computer. After the computer is shut down, the voltage of the power terminal VCC of the USB interface 110 is 0V. The first MOSFET Q1 is turned off. The voltage of the capacitor C1 remains below the threshold voltage of the second MOSFET Q2, because the voltage of the capacitor C1 cannot quickly change. The second MOSFET Q2 remains turned off. The voltage of the trigger terminal TR of the trigger U1 is at a high level. The output terminal OUT of the trigger U1 is at a low level. The third MOSFET Q3 is turned off. No current passes through the coil LA. The first contact T1 stops contact with the second contact T2, and the AC power supply 20 stops supplying power to the computer. The LED is turned off.

The power-off period of the power cycling test apparatus is set to ensure that the remaining electric charges can be released, to prevent interference. The power-off period of the power cycling test apparatus equals the charging time of the capacitor C1. The charging time of the capacitor C1 can be adjusted by altering the resistance of the variohm R1.

When the computer initiates the operating system abnormally or is shut down abnormally, the voltage of the power terminal VCC of the USB interface 110 is +5V. The third MOSFET Q3 remains on because the anode of the diode D2 is connected to the power terminal VCC of the USB interface 110. The first contact T1 remains contacted with the second contact T2. The hot line L remains connected to the PSU 400 of the computer. Function of the computer can still be tracked despite the computer having failed to power on or off, such as a dark display.

The foregoing description of the exemplary embodiments of the disclosure has been presented only for the purposes of illustration and description and is not intended to be exhaustive or to limit the disclosure to the precise forms disclosed. Many modifications and variations are possible in light of the above. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A power cycling test apparatus, comprising:
a sampling circuit comprising a first terminal connected to a first interface of a computer, a second terminal, and a third terminal, wherein the sampling circuit is operable to receive a first signal from the first interface by the first terminal, and convert the first signal to a second signal and output the second signal through the second terminal;
a controlling circuit comprising a first terminal connected to the second terminal of the sampling circuit, a second terminal connected to the third terminal of the sampling circuit, and a third terminal wherein the controlling circuit is operable to receive the first signal and the second signal and output a third signal through the third terminal of the controlling circuit; and
a powering circuit comprising a first terminal connected to the third terminal of the controlling circuit, a second terminal connected to an alternating current (AC) power supply, and a third terminal connected to a power supply unit (PSU) of the computer, wherein the powering circuit is allocated to connect the AC power supply and the PSU according to the third signal.

2. The power cycling test apparatus of claim 1, wherein the sampling circuit includes a second interface, a variohm, a first capacitor, a first metal oxide semiconductor field effect transistor (MOSFET), and a second MOSFET, wherein a first terminal of the second interface functions as the first terminal of the sampling circuit to connect to the first interface, a gate of the first MOSFET is connected to a second terminal of the second interface via a first resistor, a drain of the first MOSFET is connected to a power supply via the variohm, a source of the first MOSFET is grounded, a gate of the second MOSFET is connected to the drain of the first MOSFET via a second resistor and grounded via the first capacitor, a drain of the second MOSFET is connected to the power supply via a third resistor, a source of the second MOSFET is grounded, the drain of the second MOSFET functions as the second terminal of the sampling circuit, and the second terminal of the second interface functions as the third terminal of the sampling circuit.

3. The power cycling test apparatus of claim 2, wherein the second interface is a universal serial bus interface.

4. The power cycling test apparatus of claim 2, wherein the voltage of the power supply is +5V.

5. The power cycling test apparatus of claim 2, wherein the controlling circuit includes a trigger, a third MOSFET, a switch, a first diode, and a second diode, wherein the trigger includes a power terminal, a ground terminal, a threshold terminal, a trigger terminal, a control terminal, a reset terminal, a discharge terminal, and an output terminal, the power terminal of the trigger is connected to the power supply, the ground terminal of the trigger is grounded, the control terminal is grounded via a second capacitor, the threshold terminal is connected to the discharge terminal and is grounded via a third capacitor, the threshold terminal is also connected to the power supply via a fourth resistor, the reset terminal is connected to the power supply, the trigger terminal functions as the first terminal of the controlling circuit to connect to the drain of the second MOSFET, the output terminal of the trigger is connected to an anode of the first diode, a gate of the third MOSFET is connected to a cathode of the first diode via a fifth resistor, a source of the third MOSFET is grounded, a drain of the third MOSFET functions as the third terminal of the controlling circuit, a cathode of the second diode is connected to the gate of the third MOSFET via the fifth resistor, and an anode of the second diode functions as the second terminal of the controlling circuit.

6. The power cycling test apparatus of claim 5, wherein the controlling circuit further comprises a switch and a third diode, a first terminal of the switch is connected to the power supply, a second terminal of the switch is connected to an anode of the third diode, a cathode of the third diode is connected to the gate of the third MOSFET via the fifth resistor.

7. The power cycling test apparatus of claim 5, wherein the powering circuit comprises a relay and a third diode, the relay includes a coil, a first contact, and a second contact, a first terminal of the coil is connected to the power supply, a second terminal of the coil functions as the first terminal of the powering circuit to connect to the drain of the third MOSFET and an anode of the third diode, a cathode of the third diode is connected to the power supply, the first contact functions as the second terminal of the powering circuit to connect to a hot line of the AC power supply of the computer, and the second contact functions as the third terminal of the powering circuit to connect to the PSU.

8. The power cycling test apparatus of claim 7, wherein the second contact is also connected to the hot line of the AC power supply via a sixth resistor and a fourth capacitor in series.

9. The power cycling test apparatus of claim 7, wherein the second contact is also connected to an anode of a light emitting diode, and a cathode of the light emitting diode is connected to the a ground line of the AC power supply.
